(19) United States
(12) Patent Application Publication
(10) Pub. No.: US 2026/0128097 A1
(43) Pub. Date: May 7, 2026

(54) Memory Circuitry And Methods Used In Forming Memory Circuitry

(71) Applicant: Micron Technology, Inc., Boise, ID (US)

(72) Inventors: Naveen Kaushik, Boise, ID (US); Michael A. Smith, Boise, ID (US); Albert Fayrushin, Boise, ID (US); Anna Maria Conti, Milano (IT); Haitao Liu, Boise, ID (US)

(73) Assignee: Micron Technology, Inc., Boise, ID (US)

(21) Appl. No.: 19/324,548

(22) Filed: Sep. 10, 2025

Related U.S. Application Data
(60) Provisional application No. 63/715,315, filed on Nov. 1, 2024.

(51) Int. Cl. G11C 16/08; G11C 16/04; H10B 41/27; H10B 41/35; H10B 41/41; H10B 43/27; H10B 43/35; H10B 43/40

(52) U.S. Cl. CPC G11C 16/08; G11C 16/0483; H10B 41/27; H10B 41/35; H10B 41/41; H10B 43/27; H10B 43/35; H10B 43/40

(57) ABSTRACT

Memory circuitry comprises strings of NAND memory cells and horizontal high voltage transistors that are operatively electrically coupled with the vertical strings. The horizontal high voltage transistors individually comprise two horizontally-spaced regions having a vertical fin extending horizontally there-between. Two source/drain regions are individually in one of the two horizontally-spaced regions and individually comprise a highest-doped region that is horizontally spaced from the vertical fin and a lightly-doped region that is beneath and laterally aside the highest-doped region between the highest-doped region and the vertical fin (with the lightly-doped region being horizontally spaced from the vertical fin by an intermediate region of one of the two horizontally-spaced regions). A channel region is horizontally between the two source/drain regions and is in the vertical fin and in each intermediate region. A conductive gate is operatively over a top surface and opposing lateral side surfaces of the vertical fin and over a top surface of each intermediate region. Methods are disclosed.

### TECHNICAL FIELD

Embodiments disclosed herein pertain to memory circuitry and to methods used in forming memory circuitry

### BACKGROUND

Memory is one type of integrated circuitry and is used in computer systems for storing data. Memory may be fabricated in one or more arrays of individual memory cells. Memory cells may be written to, or read from, using digitlines (which may also be referred to as bitlines, data lines, or sense lines) and access lines (which may also be referred to as wordlines). The sense lines may conductively interconnect memory cells along columns of the array, and the access lines may conductively interconnect memory cells along rows of the array. Each memory cell may be uniquely addressed through the combination of a sense line and an access line.

Memory cells may be volatile, semi-volatile, or non-volatile. Non-volatile memory cells can store data for extended periods of time in the absence of power. Non-volatile memory is conventionally specified to be memory having a retention time of at least about 10 years. Volatile memory dissipates and is therefore refreshed/rewritten to maintain data storage. Volatile memory may have a retention time of milliseconds or less. Regardless, memory cells are configured to retain or store memory in at least two different selectable states. In a binary system, the states are considered as either a “0” or a “1”. In other systems, at least some individual memory cells may be configured to store more than two levels or states of information.

A field effect transistor is one type of electronic component that may be used in a memory cell. These transistors comprise a pair of conductive source/drain regions having a semiconductive channel region there-between. A conductive gate is adjacent the channel region and separated there-from by a thin gate insulator. Application of a suitable voltage to the gate allows current to flow from one of the source/drain regions to the other through the channel region. When the voltage is removed from the gate, current is largely prevented from flowing through the channel region. Field effect transistors may also include additional structure, for example a reversibly programmable charge-storage region as part of the gate construction between the gate insulator and the conductive gate.

Flash memory is one type of memory and has numerous uses in modern computers and devices. For instance, modern personal computers may have BIOS stored on a flash memory chip. As another example, it is becoming increasingly common for computers and other devices to utilize flash memory in solid state drives to replace conventional hard drives. As yet another example, flash memory is popular in wireless electronic devices because it enables manufacturers to support new communication protocols as they become standardized, and to provide the ability to remotely upgrade the devices for enhanced features.

NAND may be a basic architecture of integrated flash memory. A NAND cell unit comprises at least one selecting device coupled in series to a serial combination of memory cells (with the serial combination commonly being referred to as a NAND string). NAND architecture may be configured in a three-dimensional arrangement comprising vertically-stacked memory cells individually comprising a reversibly programmable vertical transistor. Control or other circuitry may be formed below the vertically-stacked memory cells. Other volatile or non-volatile memory array architectures may also comprise vertically-stacked memory cells that individually comprise a transistor.

Memory arrays may be arranged in memory pages, memory blocks and partial blocks (e.g., sub-blocks), and memory planes, for example as shown and described in any of U.S. Patent Application Publication Nos. 2015/0228651, 2016/0267984, and 2017/0140833. The memory blocks may at least in part define longitudinal outlines of individual wordlines in individual wordline tiers of vertically-stacked memory cells. Connections to these wordlines may occur in a so-called “stair-step structure” at an end or edge of an array of the vertically-stacked memory cells. The stair-step structure includes individual “stairs” (alternately termed “steps” or “stair-steps”) that define contact regions of the individual wordlines upon which elevationally-extending conductive vias contact to provide electrical access to the wordlines.

### BRIEF DESCRIPTION OF THE DRAWINGS

FIGS. 1-3 are diagrammatic views of a construction in process in accordance with some embodiments of the invention.

FIGS. 4-21 are diagrammatic sequential views of the construction of FIGS. 1-3 in process in accordance with some embodiments of the invention.

FIG. 22 is a simplified block diagram of a memory in communication with a processor as part of an electronic system, according to an embodiment.

FIGS. 23A and 23B are schematics of portions of an array of memory cells as could be used in a memory of the type described with reference to FIG. 22.

### DETAILED DESCRIPTION OF EXAMPLE EMBODIMENTS

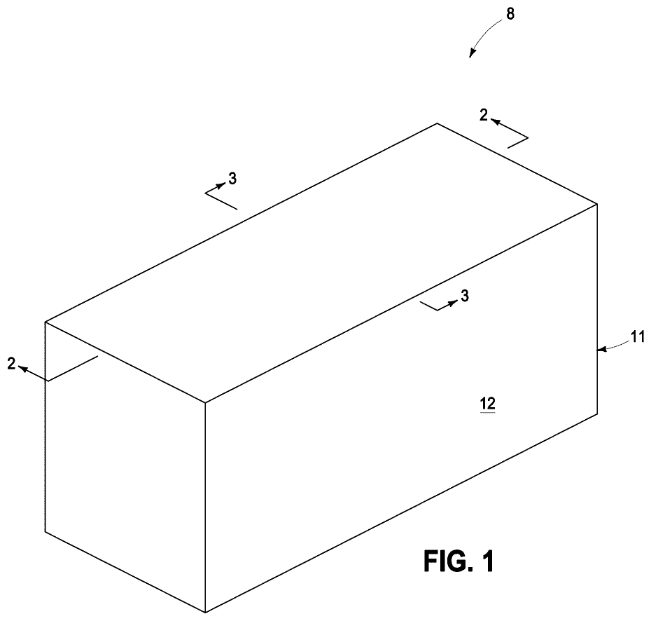

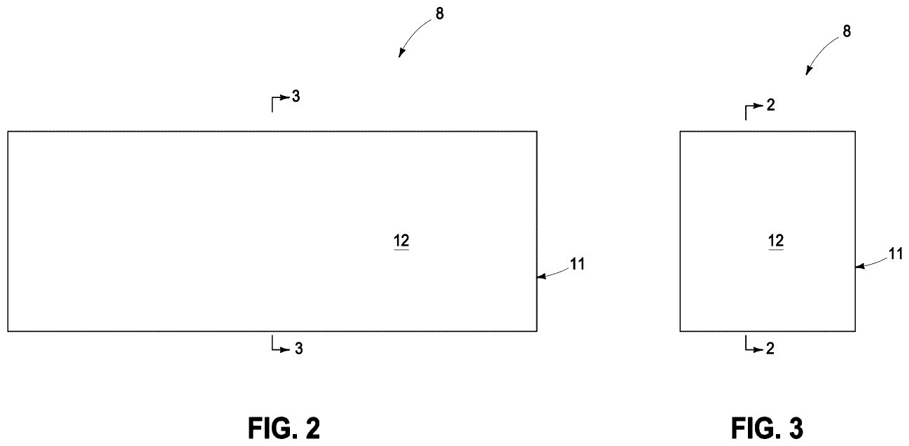

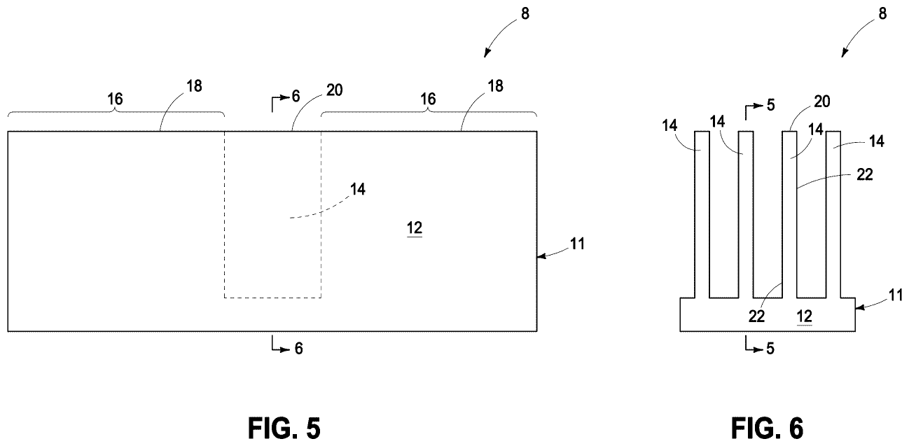

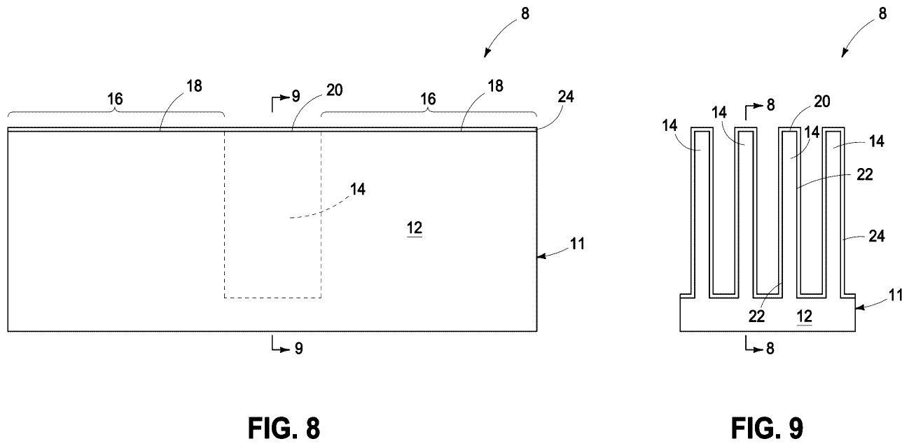

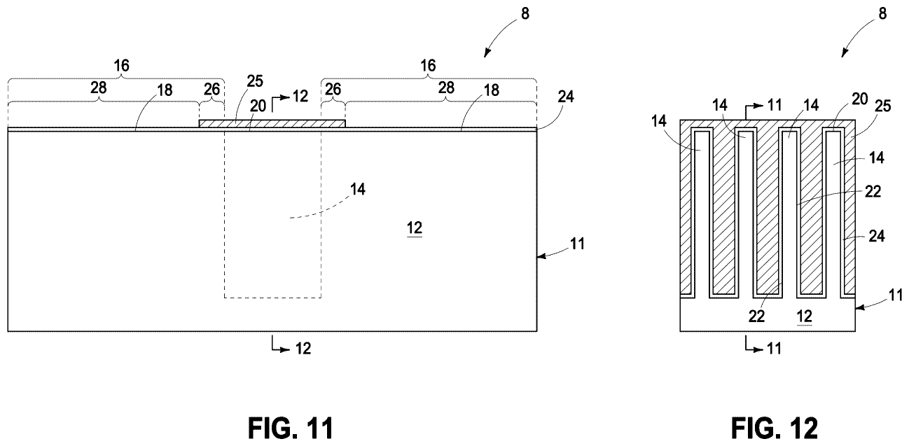

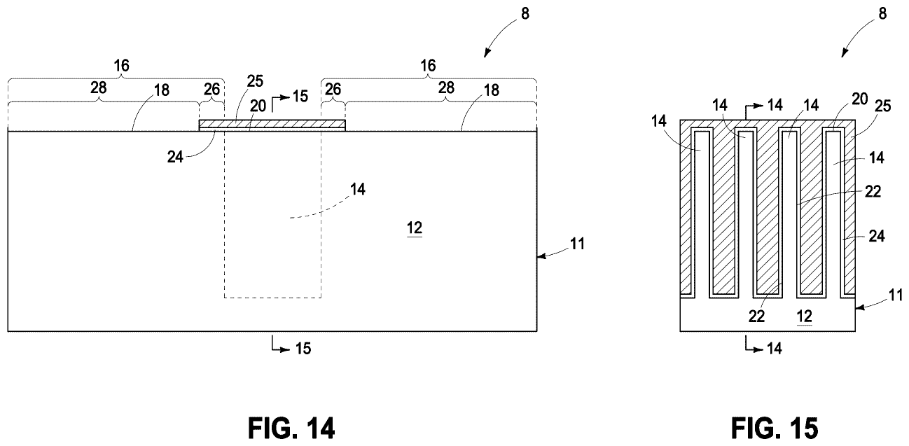

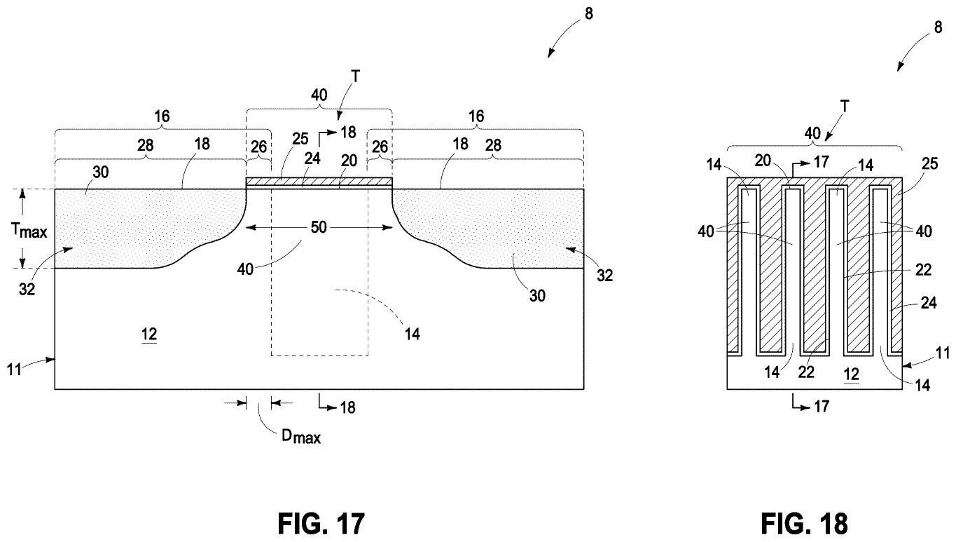

Example method embodiments used in forming memory circuitry that comprises a horizontal high voltage transistor are described with reference to FIGS. 1-23B. In this document, a horizontal high voltage transistor is a horizontal field effect transistor that is ultimately sized, configured, and electrically coupled with other circuitry components to repeatedly operate in an operative state (at least one) where high voltage is applied to the transistor gate and/or at least one of the transistor source/drain regions. In this document, high voltage is at least 15 volts (absolute value; e.g., an upper limit being 40 volts), with such high voltage typically being 20V to 30V.

FIGS. 1-3 show an example portion of a fragment of a substrate construction 8 in process that comprises a base substrate 11 that may comprise conductive/conductor/conducting, semiconductive/semiconductor/semiconducting, and/or insulative/insulator/insulating (i.e., electrically herein) materials. Materials may be aside, elevationally inward, or elevationally outward of the FIGS. 1-3-depicted material. For example, other partially or wholly fabricated components of integrated circuitry may be provided somewhere above, about, or within base substrate 11. Example base substrate 11 comprises semiconductive material 12, for example undoped or appropriately and variously doped monocrystalline and/or polycrystalline silicon, Ge, SiGe, GaAs, and/or other existing or future-developed semiconductive material. Semiconductive material 12 may be atop insulative material (e.g., a semiconductor-on-insulator construction and not shown). Semiconductive material 12 may be undoped (i.e., from 0 atoms/cm³ to 1×10¹⁰ atoms/cm³) or intrinsically doped (i.e., greater than 1×10¹⁰ atoms/cm³ to no more than 1×10¹⁸ atoms/cm³) at this point of processing to be able to function as channel material.

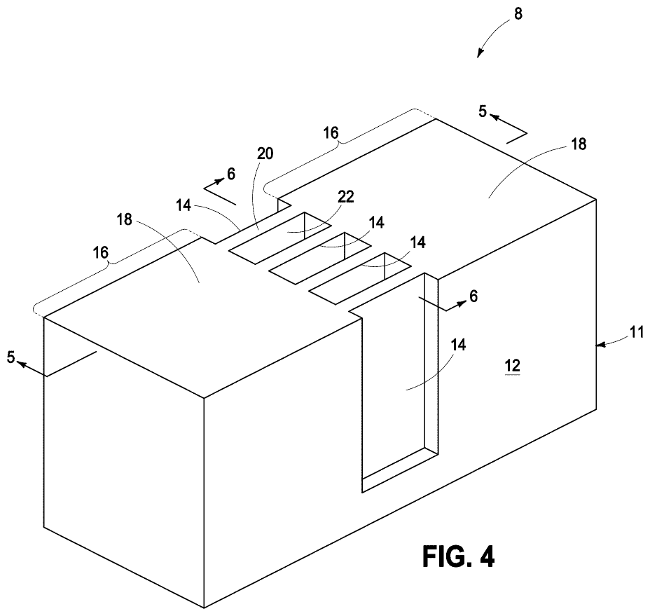

Referring to FIGS. 4-6, a vertical fin 14 (at least one) has been formed in semiconductive material 12 and extends horizontally between two horizontally-spaced regions 16 of semiconductive material 12. Multiple vertical fins 14 are shown as having been formed (e.g., four by photolithographic patterning and etch). More or fewer fins may be formed, including only one, with the description largely proceeding with respect to processing associated with only one of vertical fins 14 recognizing that such processing ideally occurs with respect to all vertical fins 14 and as is shown. Two horizontally-spaced regions 16 may be considered as individually having a top surface 18 which may be planar and exactly horizontally planar as shown. Vertical fin 14 may be considered as having a top surface 20 (e.g., that is exactly horizontally planar) and opposing lateral side surfaces 22 (e.g., that are individually planar and vertical). Vertical fin 14 may taper laterally inward and/or outward moving deeper into semiconductive material 12 (neither being shown).

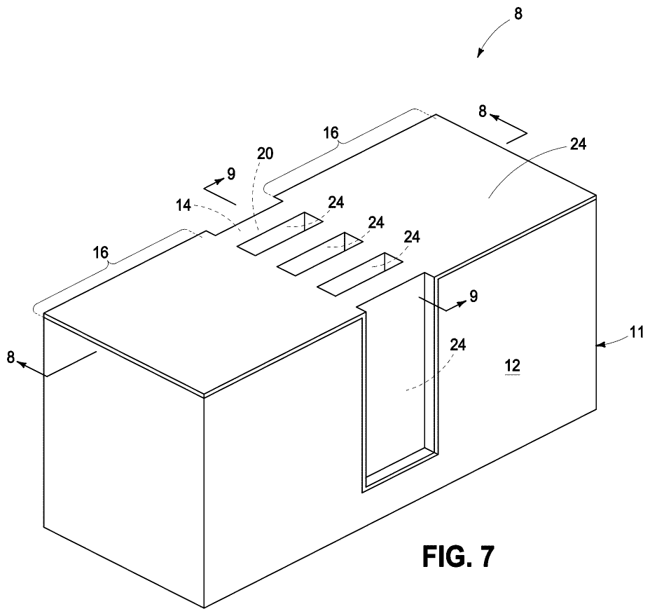

Referring to FIGS. 7-9, a gate insulator 24 (e.g., silicon dioxide and/or silicon nitride) has been formed over top surface 18 of each of two horizontally-spaced regions 16 of semiconductive material 12 and over top surface 20 and opposing lateral side surfaces 22 of vertical fin 14.

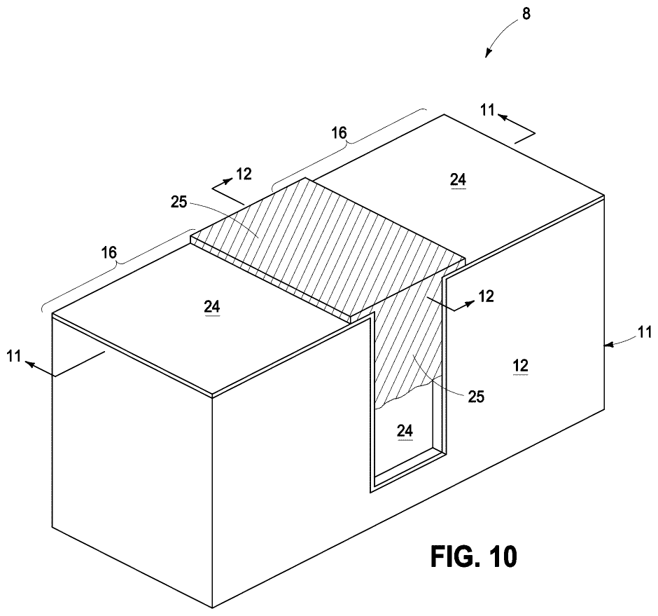

Referring to FIGS. 10-12, a conductive gate 25 (e.g., conductive metal material and/or conductively-doped semiconductive material) has been formed over gate insulator 24 and over top surface 20 and opposing lateral side surfaces 22 of vertical fin 14. Conductive gate 25 has also been formed over gate insulator 24 that is over two intermediate regions 26 of two horizontally-spaced regions 16. Intermediate regions 26 are individually horizontally between vertical fin 14 and a distal region 28 that is in individual of two horizontally-spaced regions 16. An example manner of forming conductive gate 25 is by deposition of a suitable conductive material blanketly over the depicted substrate followed by patterning using photolithographic patterning and etch thereof. Gate 25 is diagrammatically shown as being broken vertically in FIG. 10 and like figures for clarity.

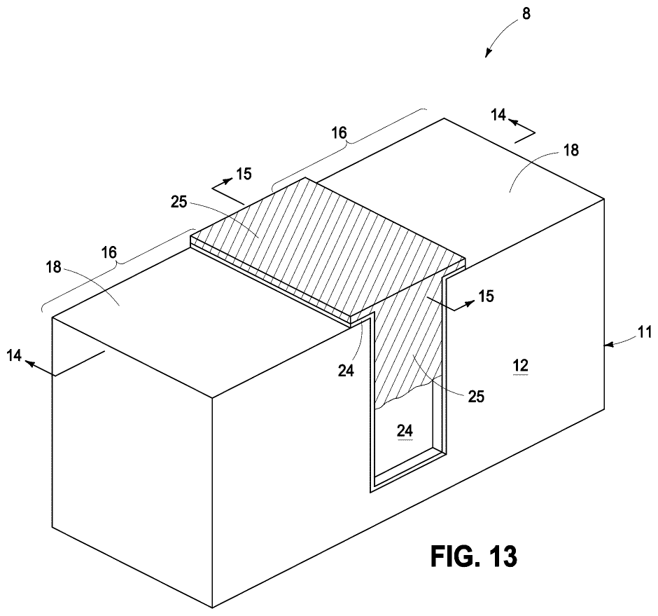

Referring to FIGS. 13-15, and in one embodiment, gate insulator 24 has been removed (e.g., by etching) from being atop top surface 18 of distal region 28 of each of two horizontally-spaced regions 16 of semiconductive material 12.

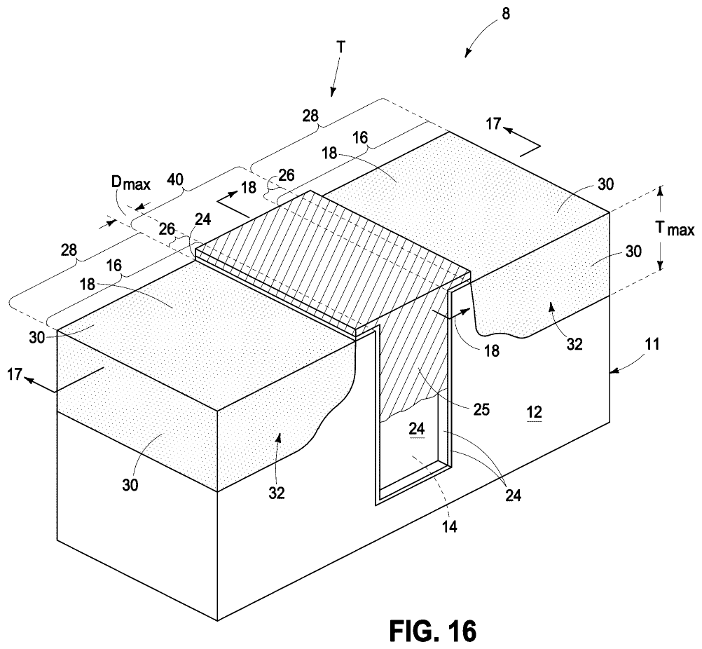

Referring to FIGS. 16-18, conductive gate 25 has been used a mask while ion implanting a conductivity-increasing dopant 30 (e.g., B if p-type or P if n-type) into semiconductive material 12 of distal region 28 that is in individual two horizontally-spaced regions 16. Conductivity-increasing dopant 30 is indicated in the figures by an individual dot of stippling, with greater stippling density indicating higher conductivity-increasing dopant concentration than comparatively lower depicted stippling density. Conductivity-increasing dopant 30 is used in forming a lightly-doped region 32 (e.g., a lightly-doped drain region) of conductivity-increasing dopant 30 in semiconductive material 12 of distal region 28 (e.g., from 1×10¹⁶ atoms/cm³ to less than 1×10¹⁹ atoms/cm³). Two intermediate regions 26 and vertical fin 14 there-between comprise a channel region 40, with the horizontal high voltage transistor being formed having a horizontal current flow direction 50 through vertical fin 14. In one embodiment where gate insulator 24 is removed from distal region 28, such occurs before the above-stated ion implanting used to form lightly-doped region 32.

Lightly-doped region 32 may be considered as having a maximum vertical thickness T_{MAX}. In one embodiment, two intermediate regions 26 individually have a maximum dimension D_{MAX} parallel horizontal current flow direction 50 that is at least 5% of maximum vertical thickness T_{MAX} of lightly-doped region 32. In some embodiments, maximum dimension D_{MAX} is at least 8%, is at least 15%, and is at least 20% of maximum vertical thickness T_{MAX}. In one embodiment, maximum dimension D_{MAX} is no more than 50% of maximum vertical thickness of T_{MAX}. In one embodiment, maximum dimension D_{MAX} is 10% to 40%, and in one such embodiment 15% to 30%, of maximum vertical thickness T_{MAX}.

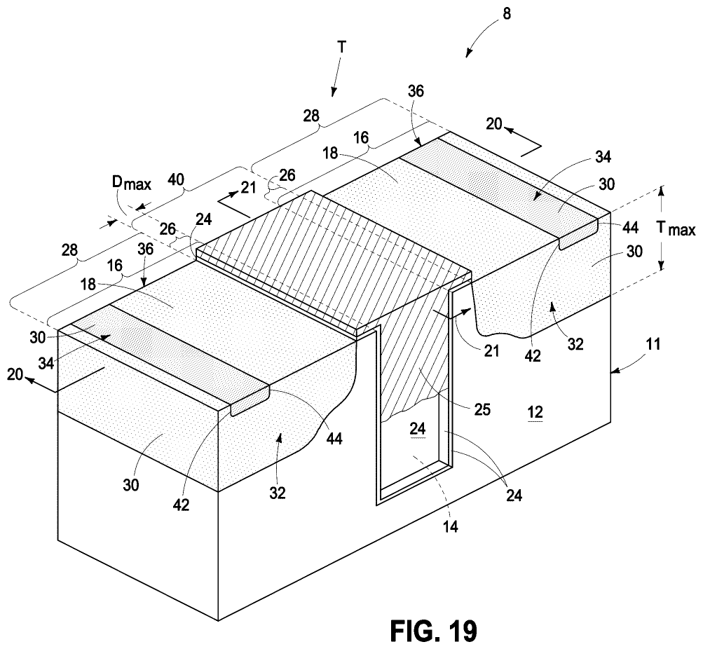

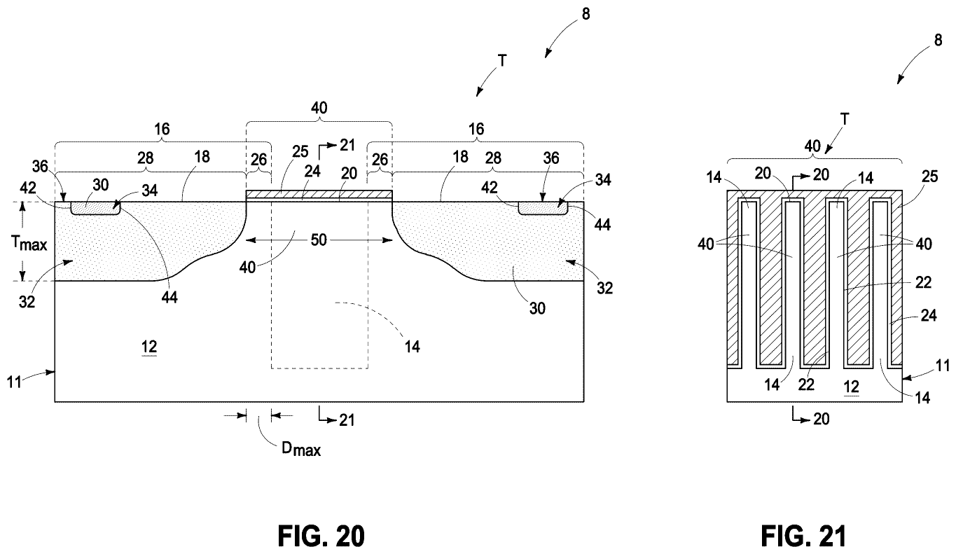

Referring to FIGS. 19-21, a highest-doped region 34 of conductivity-increasing dopant 30 (e.g., at least 1×10¹⁹ atoms/cm³; e.g., no more than 1×10²³ atoms/cm³; e.g., of the same conductively type as that of lightly-doped region 32) has been formed in distal region 28 and that is horizontally spaced from two intermediate regions 26. In one embodiment and as shown, highest-doped region 34 is formed after forming lightly-doped region 32. Highest-doped region 34 may be formed by ion implanting using a mask and subsequent activation or other processing may occur with respect to regions 32 and 34 as is known by people of skill in the art. Lightly-doped region 32 and highest-doped region 34 comprise one of two source/drain regions 36 that are individually in one of two horizontally-spaced regions 26. Source/drain regions 36, channel region 40, conductive gate 25, and gate insulator 24 comprise a horizontal high voltage transistor T. In one embodiment and as shown, lightly-doped region 32 is directly against two laterally-opposing sides 42, 44 of highest-doped region 34 in a vertical cross-section that is parallel horizontal current flow direction 50 (e.g., that of FIG. 20).

Strings of NAND memory cells are formed (before or after forming some or all of horizontal high voltage transistor T), with horizontal high voltage transistor T being operatively electrically coupled (directly or indirectly through one or more discrete components and/or other circuitry) with at least one of such strings. In one embodiment, the strings of NAND memory cells are formed to extend vertically. Of course, likely multiple such horizontal high voltage transistors T may be formed. In one embodiment, horizontal high voltage transistor T comprises a wordline driver transistor of wordline driver circuitry, with such wordline driver transistor T being directly electrically coupled to a wordline of the strings of NAND memory cells.

Any other attribute(s) or aspect(s) as shown and/or described herein with respect to other embodiments may be used in the embodiments shown and described with reference to the above embodiments.

Alternate embodiment constructions may result from method embodiments described above, or otherwise. Regardless, embodiments of the invention encompass memory arrays independent of method of manufacture. Nevertheless, such memory arrays may have any of the attributes as described herein in method embodiments. Likewise, the above-described method embodiments may incorporate, form, and/or have any of the attributes described with respect to device embodiments.

In one embodiment, memory circuitry (e.g., 8) comprises strings of NAND memory cells. Horizontal high voltage transistors (e.g., T) are operatively electrically coupled with the strings. The horizontal high voltage transistors individually comprise two horizontally-spaced regions (e.g., 16) having a vertical fin (e.g., 14) extending horizontally there-between along a horizontal current flow direction (e.g., 50) of the transistor. Two source/drain regions (e.g., 36) are individually in one of the two horizontally-spaced regions. The two source/drain regions individually comprise conductivity-increasing dopant (e.g., 30) in semiconductive material (e.g., 12). A highest-doped region (e.g., 34) of the conductivity-increasing dopant is horizontally spaced from the vertical fin. A lightly-doped region (e.g., 32) of the conductivity-increasing dopant is beneath and laterally aside the highest-doped region between the highest-doped region and the vertical fin. The lightly-doped region is horizontally spaced from the vertical fin by an intermediate region (e.g., 26) of one of the two horizontally-spaced regions. A channel region (e.g., 40) is horizontally between the two source/drain regions. The channel region is in the vertical fin and in each intermediate region that is horizontally between the lightly-doped region and the vertical fin in individual of the two horizontally-spaced regions. A conductive gate (e.g., 25) is operatively over a top surface (e.g., 20) and opposing lateral side surfaces (e.g., 22) of the vertical fin and over a top surface (e.g., 18) of each intermediate region. In one embodiment, the horizontal high voltage transistors individually comprise a wordline driver transistor of wordline driver circuitry, with the wordline driver transistor being directly electrically coupled to a wordline of the strings of NAND memory cells. Any other attribute(s) or aspect(s) as shown and/or described herein with respect to other embodiments may be used.

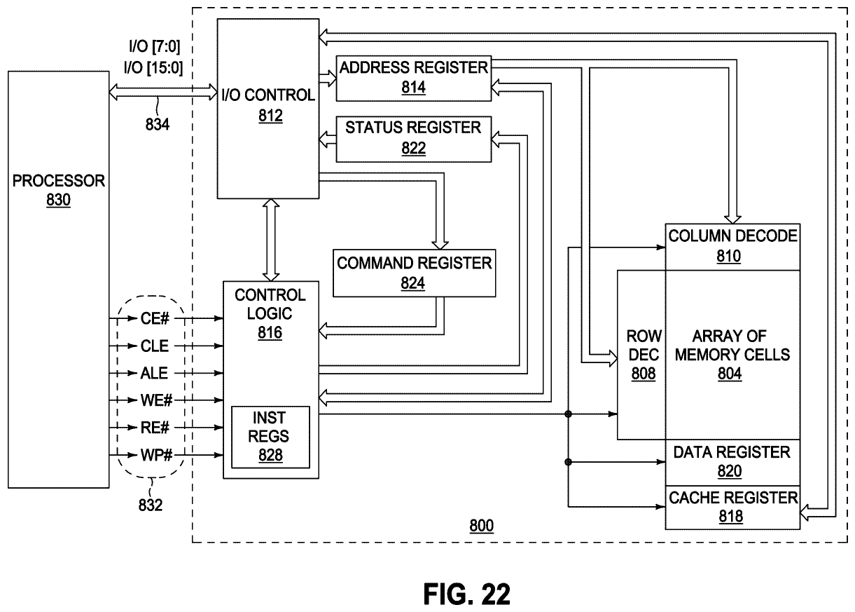

FIG. 22 is a simplified block diagram of a first apparatus, in the form of a memory (e.g., memory device) 800, in communication with a second apparatus, in the form of a processor 830, as part of a third apparatus, in the form of an electronic system, according to an embodiment. Some examples of electronic systems include personal computers, personal digital assistants (PDAs), digital cameras, digital media players, digital recorders, games, appliances, vehicles, wireless devices, mobile telephones and the like. The processor 830 (e.g., a controller external to the memory device 800) might be a memory controller or other external host device.

Memory device 800 includes an array of memory cells 804 that might be logically arranged in rows and columns. Memory cells of a logical row are typically connected to the same access line (commonly referred to as a wordline) while memory cells of a logical column are typically selectively connected to the same data line (commonly referred to as a bitline). A single access line might be associated with more than one logical row of memory cells and a single data line might be associated with more than one logical column. Memory cells (not shown in FIG. 22) of at least a portion of array of memory cells 804 are capable of being programmed to one of at least two target data states.

A row decode circuitry 808 and a column decode circuitry 810 are provided to decode address signals. Address signals are received and decoded to access the array of memory cells 804. Memory device 800 also includes input/output (I/O) control circuitry 812 to manage input of commands, addresses and data to the memory device 800 as well as output of data and status information from the memory device 800. An address register 814 is in communication with I/O control circuitry 812 and row decode circuitry 808 and column decode circuitry 810 to latch the address signals prior to decoding. A command register 824 is in communication with I/O control circuitry 812 and control logic 816 to latch incoming commands.

A controller (e.g., the control logic 816 internal to the memory device 800) controls access to the array of memory cells 804 in response to the commands and may generate status information for the external processor 830, i.e., control logic 816 is configured to perform access operations (e.g., sensing operations [which might include read operations and verify operations], programming operations and/or erase operations) on the array of memory cells 804. The control logic 816 is in communication with row decode circuitry 808 and column decode circuitry 810 to control the row decode circuitry 808 and column decode circuitry 810 in response to the addresses. The control logic 816 might include instruction registers 828 which might represent computer-usable memory for storing computer-readable instructions. For some embodiments, the instruction registers 828 might represent firmware. Alternatively, the instruction registers 828 might represent a grouping of memory cells (e.g., reserved block(s) of memory cells) of the array of memory cells 804.

Control logic 816 might also be in communication with a cache register 818. Cache register 818 latches data, either incoming or outgoing, as directed by control logic 816 to temporarily store data while the array of memory cells 804 is busy writing or reading, respectively, other data. During a programming operation (e.g., write operation), data might be passed from the cache register 818 to the data register 820 for transfer to the array of memory cells 804; then new data might be latched in the cache register 818 from the I/O control circuitry 812. During a read operation, data might be passed from the cache register 818 to the I/O control circuitry 812 for output to the external processor 830; then new data might be passed from the data register 820 to the cache register 818. The cache register 818 and/or the data register 820 might form (e.g., might form a portion of) a page buffer of the memory device 800. A page buffer might further include sensing devices (not shown in FIG. 22) to sense a data state of a memory cell of the array of memory cells 804, e.g., by sensing a state of a data line connected to that memory cell. A status register 822 might be in communication with I/O control circuitry 812 and control logic 816 to latch the status information for output to the processor 830.

Memory device 800 receives control signals at control logic 816 from processor 830 over a control link 832. The control signals might include a chip enable CE #, a command latch enable CLE, an address latch enable ALE, a write enable WE #, a read enable RE #, and a write protect WP #. Additional or alternative control signals (not shown) might be further received over control link 832 depending upon the nature of the memory device 800. Memory device 800 receives command signals (which represent commands), address signals (which represent addresses), and data signals (which represent data) from processor 830 over a multiplexed input/output (I/O) bus 834 and outputs data to processor 830 over I/O bus 834.

For example, the commands might be received over input/output (I/O) pins [7:0] of I/O bus 834 at I/O control circuitry 812 and might then be written into command register 824. The addresses might be received over input/output (I/O) pins [7:0] of I/O bus 834 at I/O control circuitry 812 and might then be written into address register 814. The data might be received over input/output (I/O) pins [7:0] for an 8-bit device or input/output (I/O) pins [15:0] for a 16-bit device at I/O control circuitry 812 and then might be written into cache register 818. The data might be subsequently written into data register 820 for programming the array of memory cells 804. For another embodiment, cache register 818 might be omitted, and the data might be written directly into data register 820. Data might also be output over input/output (I/O) pins [7:0] for an 8-bit device or input/output (I/O) pins [15:0] for a 16-bit device. Although reference might be made to I/O pins, they might include any conductive nodes providing for electrical connection to the memory device 800 by an external device (e.g., processor 830), such as conductive pads or conductive bumps as are commonly used.

It will be appreciated by those skilled in the art that additional circuitry and signals can be provided, and that the memory device 800 of FIG. 22 has been simplified. It should be recognized that the functionality of the various block components described with reference to FIG. 22 might not necessarily be segregated to distinct components or component portions of an integrated circuit device. For example, a single component or component portion of an integrated circuit device could be adapted to perform the functionality of more than one block component of FIG. 22. Alternatively, one or more components or component portions of an integrated circuit device could be combined to perform the functionality of a single block component of FIG. 22.

Additionally, while specific I/O pins are described in accordance with popular conventions for receipt and output of the various signals, it is noted that other combinations or numbers of I/O pins (or other I/O node structures) might be used in the various embodiments.

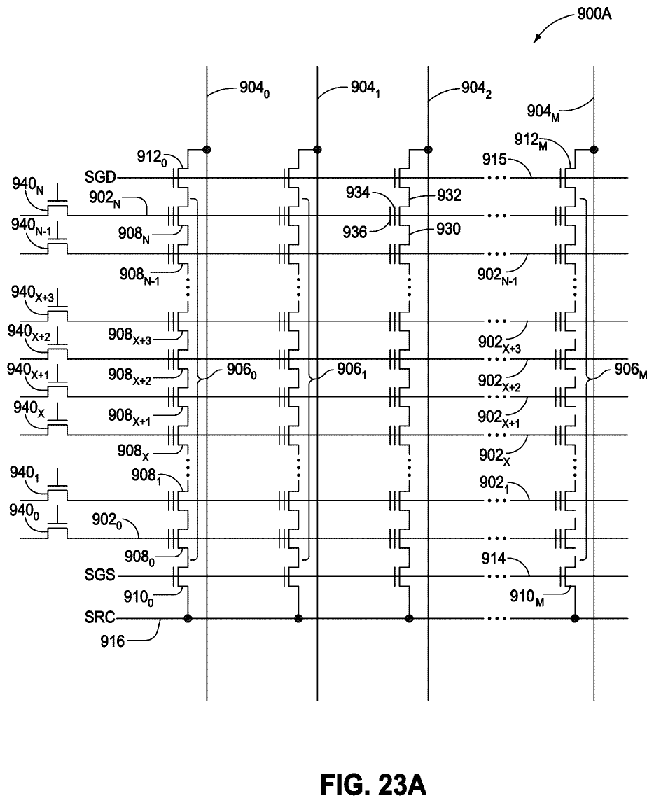

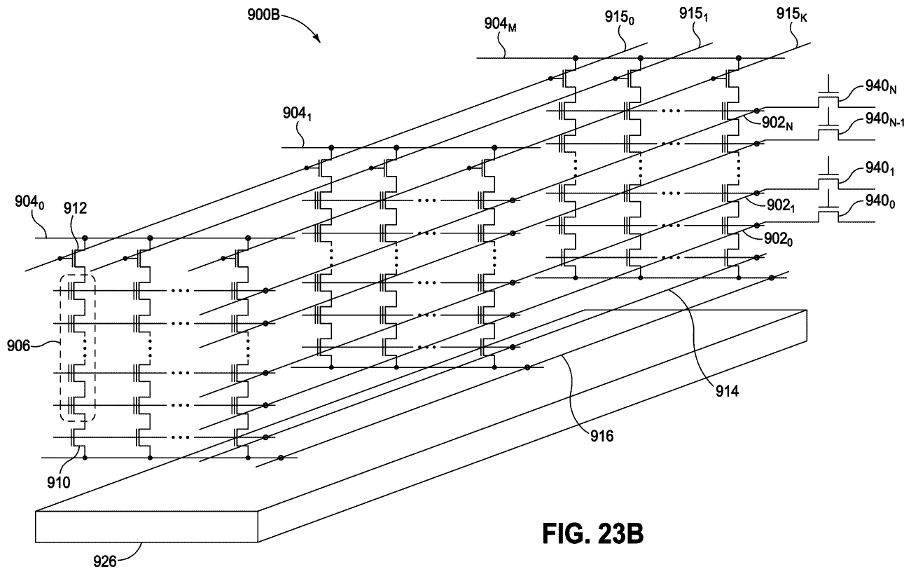

FIG. 23A is a schematic of a portion of an array of memory cells 900A, such as a NAND memory array, as could be used in a memory of the type described with reference to FIG. 22, e.g., as a portion of array of memory cells 804. Memory array 900A includes access lines (e.g., wordlines) 902₀ to 902_{N}, and data lines (e.g., bitlines) 904₀ to 904_{M}. The access lines 902 might be connected to global access lines (e.g., global wordlines), not shown in FIG. 23A, in a many-to-one relationship. For some embodiments, memory array 900A might be formed over a semiconductor that, for example, might be conductively doped to have a conductivity type, such as a p-type conductivity, e.g., to form a p-well, or an n-type conductivity, e.g., to form an n-well.

Memory array 900A might be arranged in rows (each corresponding to an access line 902) and columns (each corresponding to a data line 904). Each column might include a string of series-connected memory cells (e.g., non-volatile memory cells), such as one of NAND strings 906₀ to 906_{M}. Each NAND string 906 might be connected (e.g., selectively connected) to a common source (SRC) 916 and might include memory cells 908₀ to 908_{N}. The memory cells 908 might represent non-volatile memory cells for storage of data. The memory cells 908₀ to 908_{N} might include memory cells intended for storage of data, and might further include other memory cells not intended for storage of data, e.g., dummy memory cells. Dummy memory cells are typically not accessible to a user of the memory, and are instead typically incorporated into the string of series-connected memory cells for operational advantages that are well understood.

The memory cells 908 of each NAND string 906 might be connected in series between a select gate 910 (e.g., a field-effect transistor), such as one of the select gates 910₀ to 910_{M} (e.g., that might be source select transistors, commonly referred to as select gate source), and a select gate 912 (e.g., a field-effect transistor), such as one of the select gates 912₀ to 912_{M} (e.g., that might be drain select transistors, commonly referred to as select gate drain). Select gates 910₀ to 910_{M} might be commonly connected to a select line 914, such as a source select line (SGS), and select gates 912₀ to 912_{M} might be commonly connected to a select line 915, such as a drain select line (SGD). Although depicted as traditional field-effect transistors, the select gates 910 and 912 might utilize a structure similar to (e.g., the same as) the memory cells 908. The select gates 910 and 912 might represent a plurality of select gates connected in series, with each select gate in series configured to receive a same or independent control signal.

A source of each select gate 910 might be connected to common source 916. The drain of each select gate 910 might be connected to a memory cell 908₀ of the corresponding NAND string 906. For example, the drain of select gate 910₀ might be connected to memory cell 908₀ of the corresponding NAND string 906₀. Therefore, each select gate 910 might be configured to selectively connect a corresponding NAND string 906 to common source 916. A control gate of each select gate 910 might be connected to select line 914.

The drain of each select gate 912 might be connected to the data line 904 for the corresponding NAND string 906. For example, the drain of select gate 912₀ might be connected to the data line 904₀ for the corresponding NAND string 906₀. The source of each select gate 912 might be connected to a memory cell 908_{N} of the corresponding NAND string 906. For example, the source of select gate 912₀ might be connected to memory cell 908_{N} of the corresponding NAND string 906₀. Therefore, each select gate 912 might be configured to selectively connect a corresponding NAND string 906 to the corresponding data line 904. A control gate of each select gate 912 might be connected to select line 915.

The memory array in FIG. 23A might be a quasi-two-dimensional memory array and might have a generally planar structure, e.g., where the common source 916, NAND strings 906 and data lines 904 extend in substantially parallel planes. Alternatively, the memory array in FIG. 23A might be a three-dimensional memory array, e.g., where NAND strings 906 might extend substantially perpendicular to a plane containing the common source 916 and to a plane containing the data lines 904 that might be substantially parallel to the plane containing the common source 916.

Typical construction of memory cells 908 includes a data-storage structure 934 (e.g., a floating gate, charge trap, or other structure configured to store charge) that can determine a data state of the memory cell (e.g., through changes in threshold voltage), and a control gate 936, as shown in FIG. 23A. The data-storage structure 934 might include both conductive and dielectric structures while the control gate 936 is generally formed of one or more conductive materials. In some cases, memory cells 908 might further have a defined source/drain (e.g., source) 930 and a defined source/drain (e.g., drain) 932. Memory cells 908 have their control gates 936 connected to (and in some cases form) an access line 902.

Each access line 902₀ to 902_{N} might be connected (directly electrically coupled) to one side of the source-drain path of a corresponding transistor 940₀ to 940_{N}, commonly referred to as access line drivers. Each transistor 940₀ to 940_{N} might include transistor T of FIGS. 19-21. The other side of the source-drain path of each transistor 940₀ to 940_{N} might be selectively connected to a voltage node for biasing each corresponding access line 902₀ to 902_{N} during memory cell programming operations. With the gate (or gate segments) of a transistor 940₀ to 940_{N} biased to turn off the transistor, the channel potential of the transistor is distributed along the channel layer of the transistor as previously described.

A column of the memory cells 908 might be a NAND string 906 or a plurality of NAND strings 906 selectively connected to a given data line 904. A row of the memory cells 908 might be memory cells 908 commonly connected to a given access line 902. A row of memory cells 908 can, but need not, include all memory cells 908 commonly connected to a given access line 902. Rows of memory cells 908 might often be divided into one or more groups of physical pages of memory cells 908, and physical pages of memory cells 908 often include every other memory cell 908 commonly connected to a given access line 902. For example, memory cells 908 commonly connected to access line 902_{N} and selectively connected to even data lines 904 (e.g., data lines 904₀, 904₂, 904₄, etc.) might be one physical page of memory cells 908 (e.g., even memory cells) while memory cells 908 commonly connected to access line 902_{N} and selectively connected to odd data lines 904 (e.g., data lines 904₁, 904₃, 904₅, etc.) might be another physical page of memory cells 908 (e.g., odd memory cells). Although data lines 904₃-904₅ are not explicitly depicted in FIG. 23A, it is apparent from such figure that the data lines 904 of the array of memory cells 900A might be numbered consecutively from data line 904₀ to data line 904_{M}. Other groupings of memory cells 908 commonly connected to a given access line 902 might also define a physical page of memory cells 908. For certain memory devices, all memory cells commonly connected to a given access line might be deemed a physical page of memory cells. The portion of a physical page of memory cells (which, in some embodiments, could still be the entire row) that is read during a single read operation or programmed during a single programming operation (e.g., an upper or lower page of memory cells) might be deemed a logical page of memory cells. A block of memory cells might include those memory cells that are configured to be erased together, such as all memory cells connected to access lines 902₀ to 902_{N} (e.g., all NAND strings 906 sharing common access lines 902). Unless expressly distinguished, a reference to a page of memory cells herein refers to the memory cells of a logical page of memory cells.

FIG. 23B is another schematic of a portion of an array of memory cells 900B as could be used in a memory of the type described with reference to FIG. 22, e.g., as a portion of array of memory cells 804. Like numbered elements in FIG. 23B correspond to the description as provided with respect to FIG. 23A. FIG. 23B provides additional detail of one example of a three-dimensional NAND memory array structure. The three-dimensional NAND memory array 900B might incorporate vertical structures which might include semiconductor pillars where a portion of a pillar might act as a channel region of the memory cells of NAND strings 906. The NAND strings 906 might be each selectively connected to a data line 904₀ to 904_{M} by a select transistor 912 (e.g., that might be drain select transistors, commonly referred to as select gate drain) and to a common source 916 by a select transistor 910 (e.g., that might be source select transistors, commonly referred to as select gate source). Multiple NAND strings 906 might be selectively connected to the same data line 904. Subsets of NAND strings 906 can be connected to their respective data lines 904 by biasing the select lines 915₀ to 915_{K} to selectively activate particular select transistors 912 each between a NAND string 906 and a data line 904. The select transistors 910 can be activated by biasing the select line 914. Each access line 902 might be connected to multiple rows of memory cells of the memory array 900B and might be selectively biased via corresponding transistors 940₀ to 940_{N}. Rows of memory cells that are commonly connected to each other by a particular access line 902 might collectively be referred to as tiers.

The three-dimensional NAND memory array 900B might be formed over peripheral circuitry 926. Alternately, peripheral circuitry 926 might be above or aside memory array 900B. The peripheral circuitry 926 might represent a variety of circuitry for accessing the memory array 900B. The peripheral circuitry 926 might include complementary circuit elements. For example, the peripheral circuitry 926 might include both n-channel and p-channel transistors formed on a same semiconductor substrate, a process commonly referred to as CMOS, or complementary metal-oxide-semiconductors. Although CMOS often no longer utilizes a strict metal-oxide-semiconductor construction due to advancements in integrated circuit fabrication and design, the CMOS designation remains as a matter of convenience.

One or more horizontal high voltage transistor(s) in accordance with the invention might be a part of any block component (e.g., 812, 816, 828, 814, 822, 824, 810, 808, 820, and/or 818) of memory device 800 in the context of strings of NAND memory cells that are within example array 804, and thereby be operatively directly or indirectly electrically coupled with at least one of the strings of NAND memory cells.

Embodiments of the invention may improve over prior horizontal high voltage transistors used in NAND circuitry. For example, moving the junction (interface) of lightly-doped region 32 with channel region 40 away from fin 14 (e.g., by intermediate region 26) may improve (increase) breakdown voltage while maintaining acceptable or minimizing short-channel effect for the transistor. Such may be accomplished, in method, by using gate 25 as a self-aligned mask for formation of lightly-doped region 32.

The memory circuitry described herein (e.g., conductive vias thereof) may connect with circuitry that is on either the top or the bottom (i.e., either z-axis side) of the stack regardless of orientation of the construction in three-dimensional space and which is not material to aspects of the inventions disclosed herein. For example, and by way of example only, the conductive vias may connect with peripheral control circuitry that is beneath the stack with respect to the orientation shown in the drawings. As an alternate example, and by way of example only, the conductive vias may connect with peripheral control circuitry that is above the stack with respect to the shown orientation, for example to another substrate having such circuitry and that is bonded with the top of the stack with respect to the shown orientation. In such alternate example, the construction may be inverted from the shown orientation and then bonded with the other substrate. Further, in such alternate example, circuitry components (e.g., a common source) may be fabricated relative to the bottom of the stack with respect to the shown orientation but inverted therefrom during processing. Such circuitry components may connect with conductive vias that extend through the stack to the substrate bonded with the other side that has such peripheral control circuitry. Regardless, constructions as shown and described herein may be processed, packaged, and/or mounted in any three-dimensional spatial orientation.

The above processing(s) or construction(s) may be considered as being relative to an array of components formed as or within a single stack or single deck of such components above or as part of an underlying base substrate (albeit, the single stack/deck may have multiple tiers). Control and/or other peripheral circuitry for operating or accessing such components within an array may also be formed anywhere as part of the finished construction, and in some embodiments may be under the array (e.g., CMOS under-array). Regardless, one or more additional such stack(s)/deck(s) may be provided or fabricated above and/or below that shown in the figures or described above. Further, the array(s) of components may be the same or different relative one another in different stacks/decks and different stacks/decks may be of the same thickness or of different thicknesses relative one another. Intervening structure may be provided between immediately-vertically-adjacent stacks/decks (e.g., additional circuitry and/or dielectric layers). Also, different stacks/decks may be electrically coupled relative one another. The multiple stacks/decks may be fabricated separately and sequentially (e.g., one atop another), or two or more stacks/decks may be fabricated at essentially the same time.

The assemblies and structures discussed above may be used in integrated circuits/circuitry and may be incorporated into electronic systems. Such electronic systems may be used in, for example, memory modules, device drivers, power modules, communication modems, processor modules, and application-specific modules, and may include multilayer, multichip modules. The electronic systems may be any of a broad range of systems, such as, for example, cameras, wireless devices, displays, chip sets, set top boxes, games, lighting, vehicles, clocks, televisions, cell phones, personal computers, automobiles, industrial control systems, aircraft, etc.

In this document unless otherwise indicated, “elevational”, “higher”, “upper”, “lower”, “top”, “atop”, “bottom”, “above”, “below”, “under”, “beneath”, “up”, and “down” are generally with reference to the vertical direction. “Horizontal” refers to a general direction (i.e., within 10 degrees) along a primary substrate surface and may be relative to which the substrate is processed during fabrication, and vertical is a direction generally orthogonal thereto. Reference to “exactly horizontal” is the direction along the primary substrate surface (i.e., no degrees there-from) and may be relative to which the substrate is processed during fabrication and as shown in drawings (if any) herein. Further, “vertical” and “horizontal” as used herein are generally perpendicular directions relative one another and independent of orientation of the substrate in three-dimensional space during fabrication and/or in a finished construction. Additionally, “elevationally-extending” and “extend(ing) elevationally” refer to a direction that is angled away by at least 45° from exactly horizontal. Further, “extend(ing) elevationally”, “elevationally-extending”, “extend(ing) horizontally”, “horizontally-extending” and the like with respect to a field effect transistor are with reference to orientation of the transistor's channel length along which current flows in operation between the source/drain regions. For bipolar junction transistors, “extend(ing) elevationally” “elevationally-extending”, “extend(ing) horizontally”, “horizontally-extending” and the like, are with reference to orientation of the base length along which current flows in operation between the emitter and collector. In some embodiments, any component, feature, and/or region that extends elevationally extends vertically or within 10° of vertical.

Further, “directly above”, “directly below”, and “directly under” require at least some lateral overlap (i.e., horizontally) of two stated regions/materials/components relative one another. Also, use of “above” not preceded by “directly” only requires that some portion of the stated region/material/component that is above the other be elevationally outward of the other (i.e., independent of whether there is any lateral overlap of the two stated regions/materials/components). Analogously, use of “below” and “under” not preceded by “directly” only requires that some portion of the stated region/material/component that is below/under the other be elevationally inward of the other (i.e., independent of whether there is any lateral overlap of the two stated regions/materials/components).

Any of the materials, regions, and structures described herein may be homogenous or non-homogenous, and regardless may be continuous or discontinuous over any material which such overlie. Where one or more example composition(s) is/are provided for any material, that material may comprise, consist essentially of, or consist of such one or more composition(s). Further, unless otherwise stated, each material may be formed using any suitable existing or future-developed technique, with atomic layer deposition, chemical vapor deposition, physical vapor deposition, epitaxial growth, diffusion doping, and ion implanting being examples.

Additionally, “thickness” by itself (no preceding directional adjective) is defined as the mean straight-line distance through a given material or region perpendicularly from a closest surface of an immediately-adjacent material of different composition or of an immediately-adjacent region. Additionally, the various materials or regions described herein may be of substantially constant thickness or of variable thicknesses. If of variable thickness, thickness refers to average thickness unless otherwise indicated, and such material or region will have some minimum thickness and some maximum thickness due to the thickness being variable. As used herein, “different composition” only requires those portions of two stated materials or regions that may be directly against one another to be chemically and/or physically different, for example if such materials or regions are not homogenous. If the two stated materials or regions are not directly against one another, “different composition” only requires that those portions of the two stated materials or regions that are closest to one another be chemically and/or physically different if such materials or regions are not homogenous. In this document, a material, region, or structure is “directly against” another when there is at least some physical touching contact of the stated materials, regions, or structures relative one another. In contrast, “over”, “on”, “adjacent”, “along”, and “against” not preceded by “directly” encompass “directly against” as well as construction where intervening material(s), region(s), or structure(s) result(s) in no physical touching contact of the stated materials, regions, or structures relative one another.

Herein, regions-materials-components are “electrically coupled” relative one another if in normal operation electric current is capable of continuously flowing from one to the other and does so predominately by movement of subatomic positive and/or negative charges when such are sufficiently generated. Another electronic component may be between and electrically coupled to the regions-materials-components. In contrast, when regions-materials-components are referred to as being “directly electrically coupled”, no intervening electronic component (e.g., no diode, transistor, resistor, transducer, switch, fuse, etc.) is between the directly electrically coupled regions-materials-components.

Any use of “row” and “column” in this document is for convenience in distinguishing one series or orientation of features from another series or orientation of features and along which components have been or may be formed. “Row” and “column” are used synonymously with respect to any series of regions, components, and/or features independent of function. Regardless, the rows may be straight and/or curved and/or parallel and/or not parallel relative one another, as may be the columns. Further, the rows and columns may intersect relative one another at 90° or at one or more other angles (i.e., other than the straight angle).

The composition of any of the conductive/conductor/conducting materials herein may be conductive metal material and/or conductively-doped semiconductive/semiconductor/semiconducting material. “Metal material” is any one or combination of an elemental metal, any mixture or alloy of two or more elemental metals, and any one or more metallic compound(s).

Herein, any use of “selective” as to etch, etching, removing, removal, depositing, forming, and/or formation is such an act of one stated material relative to another stated material(s) so acted upon at a rate of at least 2:1 by volume. Further, any use of selectively depositing, selectively growing, or selectively forming is depositing, growing, or forming one material relative to another stated material or materials at a rate of at least 2:1 by volume for at least the first 75 Angstroms of depositing, growing, or forming.

Unless otherwise indicated, use of “or” herein encompasses either and both.

### Conclusion

In some embodiments, a method used in forming memory circuitry comprises forming a vertical fin in semiconductive material and that extends horizontally between two horizontally-spaced regions of the semiconductive material. A gate insulator is formed over a top surface of each of the two horizontally-spaced regions of the semiconductive material and over a top surface and opposing lateral side surfaces of the vertical fin. A conductive gate is formed over the gate insulator and over the top surface and opposing lateral side surfaces of the vertical fin. The conductive gate is also formed over the gate insulator that is over two intermediate regions of the two horizontally-spaced regions that are individually horizontally between the vertical fin and a distal region in individual of the two horizontally-spaced regions. The conductive gate is used as a mask while ion implanting a conductivity-increasing dopant into the semiconductive material of the distal region that is in the individual two horizontally-spaced regions and forming therefrom a lightly-doped region of the conductivity-increasing dopant in the semiconductive material of the distal region. The two intermediate regions and vertical fin there-between comprise a channel region. A highest-doped region of the conductivity-increasing dopant is formed in the distal region and is horizontally spaced from the two intermediate regions. The lightly-doped region and the highest-doped region comprise one of two source/drain regions that are individually in one of the two horizontally-spaced regions. The source/drain regions, the channel region, the conductive gate, and the gate insulator comprise a horizontal high voltage transistor. Strings of NAND memory cells are formed. The horizontal high voltage transistor is operatively electrically coupled with at least one of the strings.

In some embodiments, memory circuitry comprises strings of NAND memory cells. Horizontal high voltage transistors are operatively electrically coupled with the strings. The horizontal high voltage transistors individually comprise two horizontally-spaced regions having a vertical fin extending horizontally there-between along a horizontal current flow direction of the transistor. Two source/drain regions are individually in one of the two horizontally-spaced regions. The two source/drain regions individually comprise conductivity-increasing dopant in semiconductive material. A highest-doped region of the conductivity-increasing dopant is horizontally spaced from the vertical fin. A lightly-doped region of the conductivity-increasing dopant is beneath and laterally aside the highest-doped region between the highest-doped region and the vertical fin. The lightly-doped region is horizontally spaced from the vertical fin by an intermediate region of one of the two horizontally-spaced regions. A channel region is horizontally between the two source/drain regions. The channel region is in the vertical fin and in each intermediate region that is horizontally between the lightly-doped region and the vertical fin in individual of the two horizontally-spaced regions. A conductive gate is operatively over a top surface and opposing lateral side surfaces of the vertical fin and over a top surface of each intermediate region.

In some embodiments, memory circuitry comprises vertical strings of NAND memory cells. Horizontal high voltage transistors are operatively electrically coupled with the vertical strings. The horizontal high voltage transistors individually comprise a wordline driver transistor of wordline driver circuitry. The wordline driver transistor is directly electrically coupled to a wordline of the vertical strings of NAND memory cells. The horizontal high voltage transistors individually comprise two horizontally-spaced regions having multiple spaced apart vertical fins extending horizontally there-between along a horizontal current flow direction of the transistor. Two source/drain regions are individually in one of the two horizontally-spaced regions. The two source/drain regions individually comprise conductivity-increasing dopant in semiconductive material. A highest-doped region of the conductivity-increasing dopant is horizontally spaced from the vertical fins. A lightly-doped region of the conductivity-increasing dopant that is beneath and laterally aside the highest-doped region is between the highest-doped region and the vertical fins. The lightly-doped region is horizontally spaced from the vertical fins by an intermediate region of one of the two horizontally-spaced regions. The lightly-doped region is directly against two laterally-opposing sides of the highest-doped region in a vertical cross-section that is parallel the horizontal current flow direction. A channel region is horizontally between the two source/drain regions. The channel region is in the vertical fins and in each intermediate region that is horizontally between the lightly-doped region and the vertical fins in individual of the two horizontally-spaced regions. The lightly-doped region has a maximum vertical thickness. Each intermediate region has a maximum dimension parallel the horizontal current flow direction that is 5% to 50% of the maximum vertical thickness of the lightly-doped region. A conductive gate is operatively over a top surface and opposing lateral side surfaces of the vertical fins and over a top surface of each intermediate region.

In compliance with the statute, the subject matter disclosed herein has been described in language more or less specific as to structural and methodical features. It is to be understood, however, that the claims are not limited to the specific features shown and described, since the means herein disclosed comprise example embodiments. The claims are thus to be afforded full scope as literally worded, and to be appropriately interpreted in accordance with the doctrine of equivalents.

1. A method used in forming memory circuitry, comprising:
forming a vertical fin in semiconductive material and that extends horizontally between two horizontally-spaced regions of the semiconductive material;
forming a gate insulator over a top surface of each of the two horizontally-spaced regions of the semiconductive material and over a top surface and opposing lateral side surfaces of the vertical fin;
forming a conductive gate over the gate insulator and over the top surface and opposing lateral side surfaces of the vertical fin, the conductive gate also being formed over the gate insulator that is over two intermediate regions of the two horizontally-spaced regions that are individually horizontally between the vertical fin and a distal region in individual of the two horizontally-spaced regions;
using the conductive gate as a mask while ion implanting a conductivity-increasing dopant into the semiconductive material of the distal region that is in the individual two horizontally-spaced regions and forming therefrom a lightly-doped region of the conductivity-increasing dopant in the semiconductive material of the distal region, the two intermediate regions and vertical fin there-between comprising a channel region;
forming a highest-doped region of the conductivity-increasing dopant in the distal region and that is horizontally spaced from the two intermediate regions, the lightly-doped region and the highest-doped region comprising one of two source/drain regions that are individually in one of the two horizontally-spaced regions; the source/drain regions, the channel region, the conductive gate, and the gate insulator comprising a horizontal high voltage transistor; and
forming strings of NAND memory cells, the horizontal high voltage transistor being operatively electrically coupled with at least one of the strings.

2. The method of claim 1 comprising removing the gate insulator from being atop the top surface of the distal region of each of the two horizontally-spaced regions of the semiconductive material.

3. The method of claim 2 wherein the removing occurs before the ion implanting.

4. The method of claim 1 comprising forming the highest-doped region after forming the lightly-doped region.

5. The method of claim 1 comprising forming multiple of said horizontal high voltage transistor, the horizontal high voltage transistor comprising a wordline driver transistor of wordline driver circuitry, the wordline driver transistor being directly electrically coupled to a wordline of the strings of NAND memory cells.

6. The method of claim 1 comprising forming multiple of said vertical fin.

7. The method of claim 1 wherein the horizontal high voltage transistor has a horizontal current flow direction through the vertical fin, the lightly-doped region being directly against two laterally-opposing sides of the highest-doped region in a vertical cross-section that is parallel the horizontal current flow direction.

8. The method of claim 1 wherein the horizontal high voltage transistor has a horizontal current flow direction through the vertical fin and the lightly-doped region has a maximum vertical thickness, the individual of the two intermediate regions having a maximum dimension parallel the horizontal current flow direction that is at least 5% of the maximum vertical thickness of the lightly-doped region.

9. The method of claim 8 wherein the maximum dimension parallel the horizontal current flow direction is at least 8% of the maximum vertical thickness of the lightly-doped region.

10. The method of claim 9 wherein the maximum dimension parallel the horizontal current flow direction is at least 15% of the maximum vertical thickness of the lightly-doped region.

11. The method of claim 10 wherein the maximum dimension parallel the horizontal current flow direction is at least 20% of the maximum vertical thickness of the lightly-doped region.

12. The method of claim 8 wherein the maximum dimension parallel the horizontal current flow direction is no more than 50% of the maximum vertical thickness of the lightly-doped region.

13. The method of claim 12 wherein the maximum dimension parallel the horizontal current flow direction is 15% to 30% of the maximum vertical thickness of the lightly-doped region.

14. The method of claim 1 wherein the strings are formed to extend vertically.

15. Memory circuitry comprising:
strings of NAND memory cells;
horizontal high voltage transistors that are operatively electrically coupled with the strings, the horizontal high voltage transistors individually comprising:
two horizontally-spaced regions having a vertical fin extending horizontally there-between along a horizontal current flow direction of the transistor;
two source/drain regions that are individually in one of the two horizontally-spaced regions, the two source/drain regions individually comprising:
conductivity-increasing dopant in semiconductive material;
a highest-doped region of the conductivity-increasing dopant that is horizontally spaced from the vertical fin; and
a lightly-doped region of the conductivity-increasing dopant that is beneath and laterally aside the highest-doped region between the highest-doped region and the vertical fin, the lightly-doped region being horizontally spaced from the vertical fin by an intermediate region of one of the two horizontally-spaced regions;
a channel region horizontally between the two source/drain regions, the channel region being in the vertical fin and in each intermediate region that is horizontally between the lightly-doped region and the vertical fin in individual of the two horizontally-spaced regions; and
a conductive gate operatively over a top surface and opposing lateral side surfaces of the vertical fin and over a top surface of each intermediate region.

16. The memory circuitry of claim 15 wherein the horizontal high voltage transistors individually comprise a wordline driver transistor of wordline driver circuitry, the wordline driver transistor being directly electrically coupled to a wordline of the strings of NAND memory cells.

17. The memory circuitry of claim 15 wherein the horizontal high voltage transistors individually comprise multiple of said vertical fin.

18. The memory circuitry of claim 15 wherein the lightly-doped region is directly against two laterally-opposing sides of the highest-doped region in a vertical cross-section that is parallel the horizontal current flow direction.

19. The memory circuitry of claim 15 wherein the lightly-doped region has a maximum vertical thickness, each intermediate region having a maximum dimension parallel the horizontal current flow direction that is at least 5% of the maximum vertical thickness of the lightly-doped region.

20. The memory circuitry of claim 19 wherein the maximum dimension parallel the horizontal current flow direction is at least 8% of the maximum vertical thickness of the lightly-doped region.

21. The memory circuitry of claim 20 wherein the maximum dimension parallel the horizontal current flow direction is at least 15% of the maximum vertical thickness of the lightly-doped region.

22. The memory circuitry of claim 21 wherein the maximum dimension parallel the horizontal current flow direction is at least 20% of the maximum vertical thickness of the lightly-doped region.

23. The memory circuitry of claim 19 wherein the maximum dimension parallel the horizontal current flow direction is no more than 50% of the maximum vertical thickness of the lightly-doped region.

24. The memory circuitry of claim 23 wherein the maximum dimension parallel the horizontal current flow direction is 15% to 30% of the maximum vertical thickness of the lightly-doped region.

25. The memory circuitry of claim 15 wherein the strings extend vertically.

26. Memory circuitry comprising:
vertical strings of NAND memory cells;
horizontal high voltage transistors that are operatively electrically coupled with the vertical strings, the horizontal high voltage transistors individually comprising a wordline driver transistor of wordline driver circuitry, the wordline driver transistor being directly electrically coupled to a wordline of the vertical strings of NAND memory cells, the horizontal high voltage transistors individually comprising:
two horizontally-spaced regions having multiple spaced apart vertical fins extending horizontally there-between along a horizontal current flow direction of the transistor;
two source/drain regions that are individually in one of the two horizontally-spaced regions, the two source/drain regions individually comprising:
conductivity-increasing dopant in semiconductive material;
a highest-doped region of the conductivity-increasing dopant that is horizontally spaced from the vertical fins; and
a lightly-doped region of the conductivity-increasing dopant that is beneath and laterally aside the highest-doped region between the highest-doped region and the vertical fins, the lightly-doped region being horizontally spaced from the vertical fins by an intermediate region of one of the two horizontally-spaced regions the lightly-doped region being directly against two laterally-opposing sides of the highest-doped region in a vertical cross-section that is parallel the horizontal current flow direction;
a channel region horizontally between the two source/drain regions, the channel region being in the vertical fins and in each intermediate region that is horizontally between the lightly-doped region and the vertical fins in individual of the two horizontally-spaced regions, the lightly-doped region having a maximum vertical thickness, each intermediate region having a maximum dimension parallel the horizontal current flow direction that is 5% to 50% of the maximum vertical thickness of the lightly-doped region; and
a conductive gate operatively over a top surface and opposing lateral side surfaces of the vertical fins and over a top surface of each intermediate region.

27. The memory circuitry of claim 26 wherein the maximum dimension parallel the horizontal current flow direction is 10% to 40% of the maximum vertical thickness of the lightly-doped region.

28. The memory circuitry of claim 27 wherein the maximum dimension parallel the horizontal current flow direction is 15% to 30% of the maximum vertical thickness of the lightly-doped region.
